(19) United States
(12) Patent Application Publication
(10) Pub. No.: US 2010/0147360 A1
(43) Pub. Date: Jun. 17, 2010

(54) Assembly of a Photovoltaic Concentrator

(75) Inventors: Peter MORSE, Essex, MA (US); Marco ENDARA, Marlborough, MA (US)

Correspondence Address: GROSSMAN, TUCKER, PERREAULT & PFLEGER, PLLC, 55 SOUTH COMMERICAL STREET, MANCHESTER, NH, 03101, US

(73) Assignee: STELLARIS CORPORATION, North Billerica, MA (US)

(21) Appl. No.: 12/634,988

(22) Filed: Dec. 10, 2009

Related U.S. Application Data
(60) Provisional application No. 61/121,744, filed on Dec. 11, 2008.

(51) Int. Cl. H01L 31/042; H05K 13/00

(52) U.S. Cl. 136/246; 29/592.1

(57) ABSTRACT

Techniques are disclosed that facilitate the manufacturability, mechanical integrity, and performance of photovoltaic devices and assemblies. One embodiment includes assembling concentrating lenses into a structural frame such that the lenses are aligned and mechanically secure both during and upon completion of the assembly. Another embodiment includes a method of assembly where an optical coupling material is injected into a cavity within a concentrating lens that encloses a photovoltaic material. Another embodiment includes a method of assembly that creates an enclosed busway within a rail supporting the concentrating lenses, wherein a clamping cover serves to mechanically lock or otherwise secure the lenses to the supporting rail while at the same time serves as a section of the rail assembly that encloses the busway for the electrical wiring and interconnections.

### RELATED APPLICATIONS

This application claims the benefit of U.S. Provisional Patent Application No. 61/121,744, filed on Dec. 11, 2008. In addition, this application is related to U.S. Patent Application Publication No. 2008/0053515, filed Jul. 5, 2007, and titled “Apparatus and Method for Forming a Photovoltaic Device.” Each of these applications is herein incorporated by reference.

### FIELD OF THE INVENTION

The invention relates to photovoltaic devices, and more particularly, to improvements to assembly, structural and electrical connection aspects for photovoltaic device applications.

### BACKGROUND OF THE INVENTION

U.S. Patent Application Publication No. 2008/0053515 discloses techniques for encapsulating a photovoltaic device. Specifically, the techniques provide an effective way to join photovoltaic material together with a light concentrating lens in such a way that ensures high optical efficiency for generation of photovoltaic electricity, protection from environmental hazards such as water vapor penetration, electrical insulation, and allowance for differential expansion of materials in the assembly. Also disclosed are approaches for making electrical connections from a lens cell assembly to draw away the electricity produced by the photovoltaic material.

### SUMMARY

One embodiment of the present invention includes a method for fabricating a photovoltaic assembly. The method includes providing a number of concentrating lenses (e.g., 1 to 20 lenses), each having photovoltaic material. The method continues with providing a supporting rail, and securing each of the concentrating lenses to the supporting rail with a clamping cover, wherein the clamping cover also provides a busway for electrical wiring and interconnections associated with the photovoltaic material. Prior to securing each of the concentrating lenses to the supporting rail, the method may further include injecting an optical coupling material into a cavity within each of the concentrating lenses. In one such case, the optical coupling material is injected into a hole formed in a recess at an end of each concentrating lens, and the hole is blocked by the supporting rail when the corresponding concentrating lens is secured to the supporting rail. Prior to securing each of the concentrating lenses to the supporting rail, the method may include assembling each of the concentrating lenses to the supporting rail such that the concentrating lenses are aligned and mechanically secure during assembling process. In one particular case, each of the concentrating lenses includes a hook-shaped end that is configured to interface with a complementary shape and geometry in the supporting rail, so that each concentrating lens can be temporarily secured to the supporting rail such that other concentrating lenses can be assembled adjacent to it. In one such case, once a certain number of concentrating lenses have been temporarily secured to the supporting rail, the concentrating lenses are locked in place by the clamping cover. In another particular case, securing each of the concentrating lenses to the supporting rail with a clamping cover comprises engaging one end of the clamping cover with a hook profile of at least one concentrating lens and then rotating an opposing end of the clamping cover into a locking interface formed between the clamping cover an the supporting rail. The method may include fusing concentrating lens and supporting rail parts together.

Another embodiment of the present invention provides a photovoltaic system. The system includes a number of concentrating lenses, each having photovoltaic material. The system further includes a supporting rail. The system further includes a clamping cover for securing each of the concentrating lenses into the supporting rail with, and for providing a busway for electrical wiring and interconnections associated with the photovoltaic material. In some cases, the system may include an optical coupling material in a cavity within each of the concentrating lenses. In one such case, the optical coupling material is injected into a hole formed in a recess at an end of each concentrating lens, and the hole is blocked by the supporting rail when the corresponding concentrating lens is secured into the supporting rail. In one particular case, each of the concentrating lenses includes a hook-shaped end that is configured to interface with a complementary shape and geometry in the supporting rail, so that each concentrating lens can be temporarily secured to the supporting rail such that other concentrating lenses can be assembled adjacent to it, prior to installing the clamping cover. In another particular case, concentrating lens and supporting rail parts can be fused together at one or more locations. In another particular case, each concentrating lens includes a filling hole for injecting optical coupling material, the hole being formed in a recess at an end of the concentrating lens, and connecting an exterior of the lens to a photovoltaic cavity in the lens that includes the photovoltaic material. In one such case, a lower part of the filling hole is tapered to provide a seal when a tapered nozzle is inserted into the hole to fill the photovoltaic cavity with the optical coupling material. Here, an upper part of the filling hole can be wider than the tip of a tapered nozzle. In another such case, each concentrating lens further includes a vent that allows for air to escape when the optically coupling material is injected into the photovoltaic cavity via the filling hole. In another particular case, one end of the clamping cover is configured to engage with a hook profile of at least one concentrating lens and an opposing end of the clamping cover is configured to be rotated into a locking interface formed between the clamping cover an the supporting rail. Variations on this system will be apparent in light of this disclosure.

For instance, in another embodiment of the present invention, the system photovoltaic system includes a number of concentrating lenses, each having photovoltaic material and optical coupling material in a cavity within each concentrating lens. The system further includes a supporting rail. The system further includes a clamping cover for securing each of the concentrating lenses into the supporting rail with, and for providing a busway for electrical wiring and interconnections associated with the photovoltaic material. One end of the clamping cover is configured to engage with a hook profile of at least one concentrating lens and an opposing end of the clamping cover is configured to be rotated into a locking interface formed between the clamping cover an the supporting rail. Each of the concentrating lenses may include, for example, a hook-shaped end that is configured to interface with a complementary shape and geometry in the supporting rail, so that each concentrating lens can be temporarily secured to the supporting rail such that other concentrating lenses can be assembled adjacent to it, prior to installing the clamping cover.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1 shows an isometric pictorial view of the end of a concentrating lens assembly configured in accordance with an embodiment of the present invention.

FIG. 2 shows a pictorial view of a plurality of concentrating lenses assembled into a supporting rail, in accordance with an embodiment of the present invention.

FIG. 3 shows a sectional view of the assembly of a concentrating lens to a supporting rail with a clamping cover partially in place, in accordance with an embodiment of the present invention.

FIG. 4 shows a sectional view of the assembly of a concentrating lens to a supporting rail with a clamping cover fully in place, in accordance with an embodiment of the present invention.

FIG. 5 shows a pictorial view of a section of a plurality of concentrating lenses assembled to a supporting rail with a clamping cover partially in place, in accordance with an embodiment of the present invention.

### DETAILED DESCRIPTION

Techniques are disclosed that facilitate the manufacturability, mechanical integrity, and performance of photovoltaic devices. In particular, embodiments of the present invention include improvements to assembly, structural, and/or electrical connection aspects for photovoltaic device applications. For instance, the techniques facilitate the precise and positive alignment of individual concentrating lenses into a photovoltaic module assembly, as well as a secure way of introducing electrical connections into a common busway. The techniques further include a method for injecting and then sealing an optical coupling material into a concentrating lens, and a method for locking the assembly of lenses into a supporting member while at the same time creating a sealed busway that is protected from the environment. A number of photovoltaic devices and assemblies will be apparent in light of this disclosure.

General Overview

A photovoltaic device configured in accordance with one specific embodiment can be created using the techniques described herein, whereby an individual concentrating lens is first aligned and then subsequently secured into a supporting rail assembly. In one such specific case, a shape in the form of a hook at the end of an individual lens is configured to engage a void of approximately similar shape and geometry in a supporting rail assembly. By positioning the concentrating lens into place, the hook-shape at the end of the concentrating lens engages the corresponding void in the supporting rail, thereby ensuring that the concentrating lens is positioned accurately in relation to the supporting rail and that the lens is temporarily secured to the supporting rail such that other concentrating lenses can be assembled adjacent to it.

In addition, when a certain number of concentrating lenses have been temporarily assembled into and positioned with respect to the supporting rail, they can be locked in place by a clamping cover added to the supporting rail, and finally secured, if desired, by fusing the distinct concentrating lenses and supporting rail parts together using, for example, solvent welding, ultrasonic welding, or any other suitable fusing or bonding techniques.

A photovoltaic device configured in accordance with another specific embodiment is created by injecting an optical coupling material into a cavity within the concentrating lens that houses photovoltaic material. In one such specific case, a hole is formed in a recess in the end-shape formed at the end of the concentrating lens. The hole effectively connects the exterior of the lens to the cavity in the lens for the photovoltaic material.

The lower part of the hole can be tapered to provide a seal when a tapered nozzle is inserted into the hole at the time the photovoltaic cavity is filled with an optical coupling material. The taper provides for a forced seal when a similarly configured nozzle is pushed into the hole. The upper part of the hole can be formed approximately in the shape of a cylinder. The cylindrical shape, having a width wider than the tip of a tapered fill nozzle, prevents direct contact between the tip of the nozzle and the sides of the hole thereby eliminating the possibility of contact and deposit of the optical coupling material on the sides of the hole. This arrangement can be used to help prevent contamination of the hole surface so that a sealing compound will sufficiently adhere when that compound is added to seal the optically coupling material in the photovoltaic cavity. A similar hole can be provided, for example, at the other end of the concentrating lens, which allows for air to escape when the optical coupling material is injected into the photovoltaic cavity via the other hole.

When the concentrating lens is assembled into the supporting rail as previously described, the mating parts of the shaped-end of the lens and the supporting rail effectively cover and enclose the top of the injection hole (or holes). If the assembled lenses and rail parts are further fused by solvent welding or other types of fusion/bonding, this will provide a further level of seal so that the optical coupling material is prevented from escaping from the photovoltaic cavity in the lens. A number of such material injection and assembly schemes will be apparent in light of this disclosure, and the present invention is not intended to be limited to any particular one.

A photovoltaic device configured in accordance with another specific embodiment is created by mechanically locking the concentrating lenses into the supporting rail while at the same time providing a second part of the supporting rail in the form of a clamping cover. This clamping cover can be used to further serve as part of the busway/passageway walls for electrical connections running between the individual concentrating lenses.

Note that the various features described herein can be combined into a single embodiment to provide a photovoltaic concentrator assembly having benefits associated with all such features. Alternatively, any one or more of the various features described herein can be selectively used to fabricate, and/or be integrated into, a photovoltaic concentrator assembly as desired.

Concentrator Lens Cell

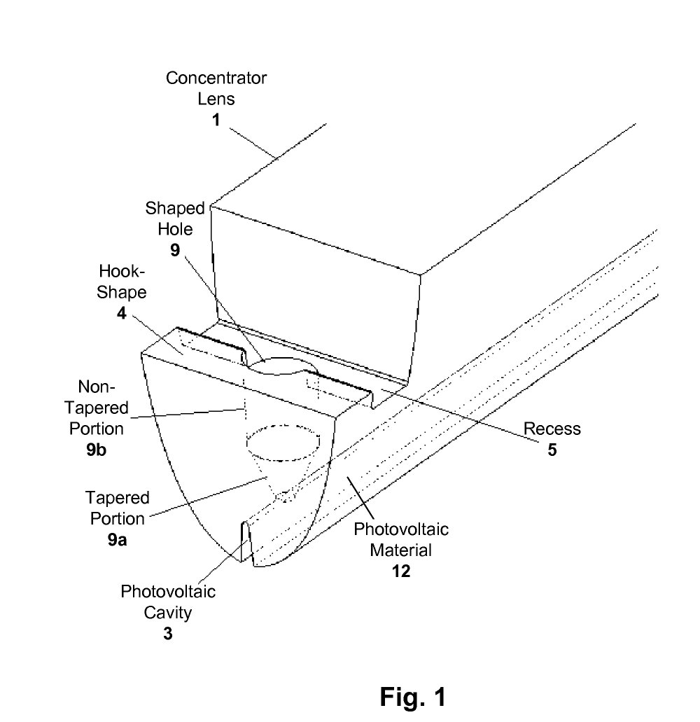

Referring to the drawings, FIG. 1 describes a concentrator lens cell 1 with a number of features configured to facilitate the construction of a photovoltaic concentrating module. In this example embodiment, the features include a hook-shape 4 and a recess 5 formed in the end of the concentrator lens 1. In addition, a shaped hole 9 is provided, which is divided into two sections: a lower tapered section 9a and an un-tapered section 9b. As can be further seen, the lower tapered section 9a is fluidly coupled with a photovoltaic cavity 3.

The hole 9 is cylindrical in this example embodiment, but other suitable shapes can be used as well. For instance, the hole 9 could include a square block section for 9b and a pyramid-shaped section for 9a. As previously explained, a similar hole can be provided, for example, at the other end of the concentrating lens (not shown), for allowing air to escape when the optical coupling material is injected into the photovoltaic cavity via the other hole. Alternatively, hole 9 can be configured with a secondary channel or vent that provides a similar venting mechanism. Numerous venting schemes will be apparent in light of this disclosure. In any such cases, the hole 9 provides a means for injecting an optical coupling material into the photovoltaic cavity 3.

The optical coupling material may include, for example, transparent dielectric fluids or gels, such as those described in the previously incorporated U.S. Patent Application Publication No. 2008/0053515. For instance, the optical coupling material may be, for example, mineral oil, a paraffin oil, or low molecular weight hydrocarbon or a grease and/or wax having a molecular weight of less than or equal to about 15,000. The optical coupling material may also include glycerin, but other types of transparent oils, fluids or gels may be used as well, including vegetable oils (oils sourced from plants). The optical coupling material may also have refractive index that is equal to or within about +/−20% of the value of the refractive index of the lens 1. The optical coupling material may also be generally hydrophobic (not miscible with water). For example, the optical coupling material may include a silicon based fluid, such as a fluid based upon a relatively lower molecular weight polysiloxane (e.g., polydimethylsiloxane or PDMS) having an average molecular weight (Mn) of equal to or less than about 5000. In addition, such fluids may provide thermal stability over the temperatures of application (e.g., −50° C. to about 125° C.) and avoid gellation. In addition, the fluid may be selected such that it has a relatively low permeability to diffusion of water. Fluids resulting in a water vapor transmission rate of less than or equal to 0.5 g/m²-day at 25° C. and 50% relative humidity may therefore provide superior protection again corrosion of the photovoltaic material by water vapor.

In a more general sense, the optical coupling materials can be any substance, substantially transparent, that provides either continuity of refractive index or a refractive index intermediate to those materials on either side of it, such that optical losses due to reflections at interfaces of materials are minimized.

With further reference to FIG. 1, the concentrating lens 1 encloses a photovoltaic material 12. In this example embodiment, the photovoltaic material 12 is in a vertical position with respect to the concentrating lens 1. Such an embodiment may be appropriate, for example, when the lens 1 design incorporates a bi-facial photovoltaic cavity 3 in order to generate electrical energy using both sides of the photovoltaic cell material 12. In other embodiments, the photovoltaic material 12 may be on the bottom surface of the lens 1 (in a horizontal position with respect to the concentrating lens 1). Any number of other suitable configurations for the photovoltaic material 12 will be apparent in light of this disclosure, including combinations those discussed here.

The concentrating lens cell 1 can be made from a number suitable materials. In one particular embodiment, the concentrating lens cell 1 is made from a polymer such as acrylic or polycarbonate, but other embodiments could use other materials such as glass and/or other suitable polymers. The concentrating lens cell 1 can be formed, for example, using injection molding techniques in conjunction with a mold that is shaped to provide the features shown in FIG. 1. Alternatively, the lens cell 1 can be formed by machining a block of cell 1 material to include the features shown in FIG. 1. Note that the hole 9 can be formed using a mold, drilled or otherwise machined. Combinations of molding, machining, etc may be used.

Photovoltaic Concentrator Lens Assembly

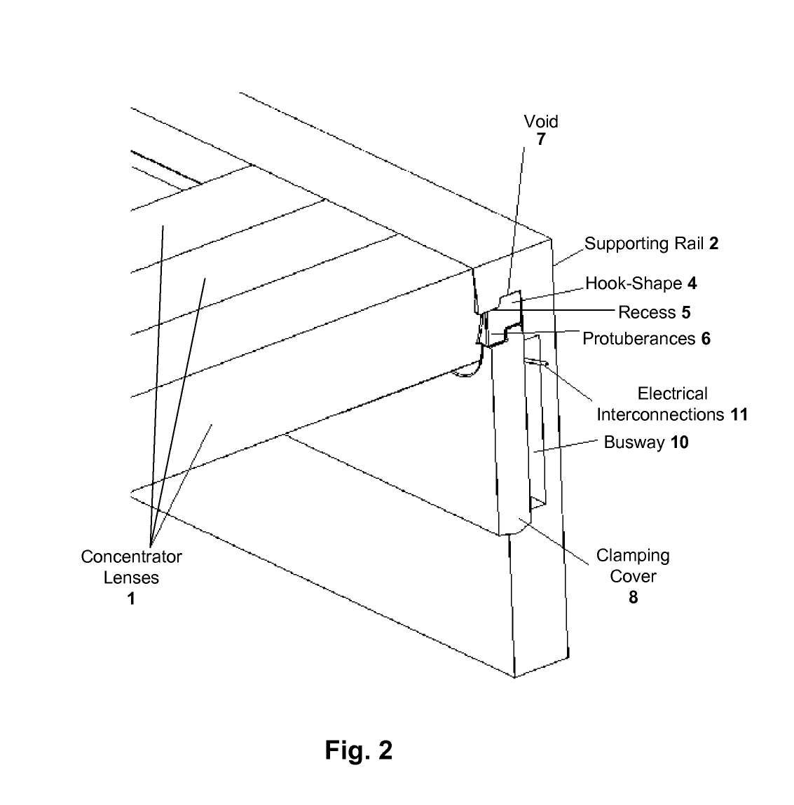

FIG. 2 shows a pictorial view of a plurality of concentrating lenses 1 assembled into a supporting rail 2, in accordance with an embodiment of the present invention. As can be seen, the hook-shape 4 and recess 5 are designed to mate with a geometrically similar void 7 in a supporting rail 2. As can further be seen from FIG. 2, a plurality of concentrating lenses 1 can be assembled adjacent to each other into a supporting rail 2 to form a photovoltaic module.

The insertion of the hook-shape 4 and recess 5 of the lens 1 into void 7 may serve a number of purposes. For instance, the alignment of the parts ensures that the top surface of one lens 1 is substantially in the same plane as the other lenses 1. Also, the supporting rail 2 temporarily holds the concentrating lenses 1 in place so that electrical checks can be made on the photovoltaics incorporated into the lenses 1. If an electrical defect is found, a concentrating lens 1 can be removed and replaced by another, prior to permanently fixing the lenses into the overall assembly. In addition, the extension of the lens 1 by its hook-shaped 4 and recessed 5 end, when secured in place in void 7 of support rail 2, prevents the lens from being uplifted or otherwise inappropriately moved in a completed assembly (thereby eliminating subsequent alignment problems). In addition, the mating geometry of void 7 in the supporting rail 2 effectively covers the optical coupling fill hole 9 when the assembly is completed, further adding to the integrity of the seal supplied for the optical coupling material.

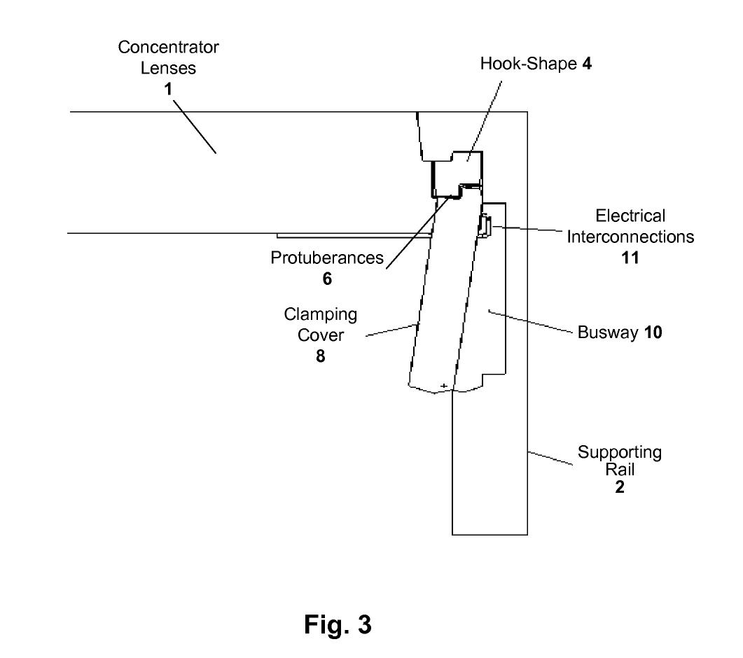

Again referring to FIG. 2, a clamping cover 8 is provided and may serve a number of functions. For instance, clamping cover 8 forms an enclosing wall for an electrical conduit or busway 10 formed by creating a void in the supporting rail 2. This conduit or busway 10 houses the electrical interconnections 11 and common bus wires of the concentrating lenses 1. The concentrating lenses 1 can be further configured at their ends to include protuberances 6. As can further be seen in FIG. 2, these protuberances 6 essentially provide a hook-shape profile configured to engage a complementary profile of the clamping cover 8, such that the clamping cover 8 can support the concentrating lenses 1 at the protuberances 6. The clamping cover 8 will be discussed in more detail with reference to FIGS. 3-5. The electrical interconnections 11 are typically in the form of wires and/or electrodes electrically attached to edges of the photovoltaic material 12 enclosed in lens 1, and may pass through the photovoltaic cavity 3 and into the busway 10. Alternatively, the concentrating lens 1 may further include a dedicated passageway provided for the electrical interconnections 11 to pass through into the busway 10.

The supporting rail 2 can be made from, for example, the same materials used to form the concentrating lens cell 1 as previously described (e.g., glass, acrylic, polycarbonate, and/or other polymers), and in a similar fashion (e.g., injection molding and/or machining), and that previous discussion is equally applicable here. Alternatively, supporting rail 2 can be made from other materials, such as aluminum, steel, PVC, etc. The materials selected should be appropriate for conditions that the given application will provide.

Clamping Cover

FIG. 3 shows a sectional view of the assembly of a concentrating lens 1 to a supporting rail 2 with a clamping cover 8 partially in place, in accordance with an embodiment of the present invention. As previously explained, the clamping cover 8 forms an enclosing wall for an electrical busway 10, essentially by creating a passageway in the supporting rail 2. Another function of the clamping cover 8 is that it supports and locks into place the assembly of the concentrating lenses 1 and supporting rail 2. In more detail, and with reference to FIG. 3, the clamping cover 8 is shown as it would be rotated into position, mating to the bottom of the end protuberances 6 of the concentrating lens 1 and forming a wall of the busway 10.

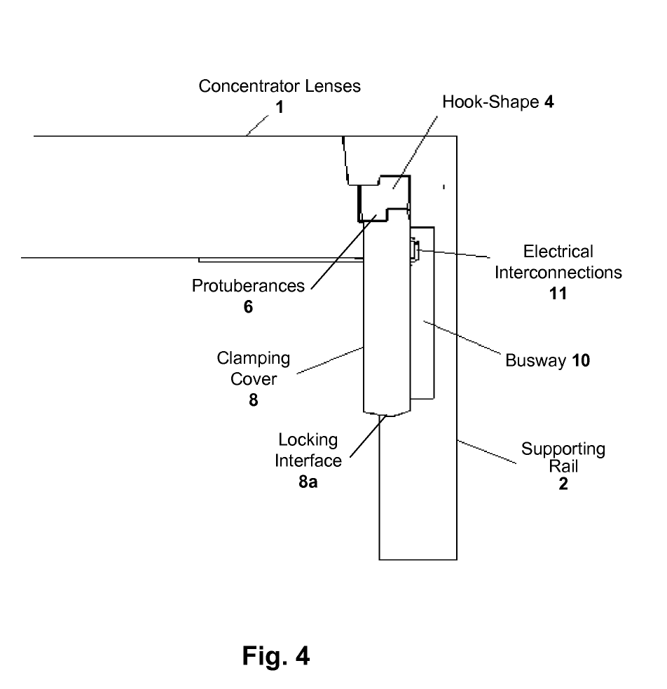

When fully rotated into position, as can be seen in FIG. 4, the bottom of the clamping cover 8, with a substantially V or U shaped profile as shown (generally shown at 8a), or any other suitable shape that allows the cover 8 to effectively snap or otherwise engage into its final position, thereby locking itself and the concentrating lens 1 into place. Any number of suitable snapping/locking interfaces 8a can be used here, as will be apparent in light of this disclosure. The mechanical integrity of the entire assembly can be further enhanced, for example, by fusing or otherwise bonding the parts together using techniques such as solvent, thermal or ultrasonic welding.

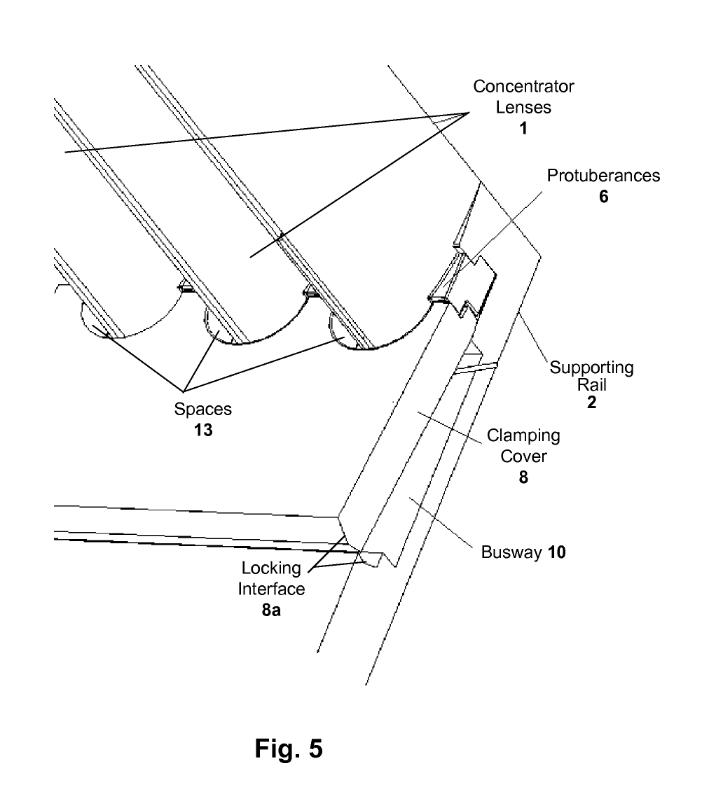

FIG. 5 shows an oblique pictorial view further demonstrating functionality of the clamping cover 8. In particular, this example embodiment shows how the clamping cover 8 can be configured to support the concentrating lenses 1 at the protuberances 6 that are part of the concentrating lenses 1. FIG. 5 also shows spaces 13 that are provided between the lenses 1 and the clamping cover 8, such that weight of the lens assembly does not cause the clamping cover 8 to press on the bottom of the lens 1 and possibly damage the photovoltaic material 12 inside it; rather the weight is carried by the lens protuberances 6 (and locking interface 8a). Further note the interface between the clamping cover 8 and the protuberances 6 of the lens 1 can be configured in a similar fashion to the hook-shape 4 and recess 5 profile as previously discussed. Other suitable interfaces can be used as well, as will be apparent in light of this disclosure.

The clamping cover 8 can be made from, for example, the same materials used to form the concentrating lens cell 1 and/or supporting rail 2 as previously described (e.g., glass, acrylic, polycarbonate, and/or other polymers), and in a similar fashion (e.g., injection molding and/or machining), and that previous discussion is equally applicable here. Alternatively, clamping cover 8 can be made from other materials, such as aluminum, steel, PVC, etc. The materials selected should be appropriate for conditions that the given application will provide.

Injection of Optical Coupling Material

As previously explained, hole 9 provides a means for injecting an optical coupling material into the photovoltaic cavity 3. In one example embodiment, a hydraulic needle (not shown) with a tapered tip is inserted into the filling hole 9. The tapered tip of the needle can be shaped to mate with the tapered hole section 9a, and with sufficient mechanical force provides a seal preventing the leakage of optical coupling material. After filling, the needle is withdrawn, and any possible residue of the optical coupling material will not contaminate the sides of the upper section 9b as its diameter is greater than the tip of the needle.

Thus, after filling the photovoltaic cavity 3 with optical coupling material, a sealant can be introduced into the upper hole section 9b to prevent leakage of the optical coupling material. A bottom cover for the photovoltaic cavity 3 (not shown) may also be provided, as sometimes done. Recall that the seal can be further enhanced when the lens 1 is assembled into the supporting rail 2 and their respective parts mate together. Moreover, this seal is even further enhanced if the various parts of the assembly are fused together by the means discussed above.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

What is claimed is:

1. A method for fabricating a photovoltaic assembly, comprising:
providing a number of concentrating lenses, each having photovoltaic material;
providing a supporting rail; and
securing each of the concentrating lenses to the supporting rail with a clamping cover, wherein the clamping cover also provides a busway for electrical wiring and interconnections associated with the photovoltaic material.

2. The method of claim 1 wherein prior to securing each of the concentrating lenses to the supporting rail, the method further comprises:
injecting an optical coupling material into a cavity within each of the concentrating lenses.

3. The method of claim 2 wherein the optical coupling material is injected into a hole formed in a recess at an end of each concentrating lens, and the hole is blocked by the supporting rail when the corresponding concentrating lens is secured to the supporting rail.

4. The method of claim 1 wherein prior to securing each of the concentrating lenses to the supporting rail, the method further comprises:
assembling each of the concentrating lenses to the supporting rail such that the concentrating lenses are aligned and mechanically secure during assembling process.

5. The method of claim 1 wherein each of the concentrating lenses includes a hook-shaped end that is configured to interface with a complementary shape and geometry in the supporting rail, so that each concentrating lens can be temporarily secured to the supporting rail such that other concentrating lenses can be assembled adjacent to it.

6. The method of claim 5 wherein once a certain number of concentrating lenses have been temporarily secured to the supporting rail, the concentrating lenses are locked in place by the clamping cover.

7. The method of claim 1 wherein securing each of the concentrating lenses to the supporting rail with a clamping cover comprises engaging one end of the clamping cover with a hook profile of at least one concentrating lens and then rotating an opposing end of the clamping cover into a locking interface formed between the clamping cover an the supporting rail.

8. The method of claim 1 further comprising:
fusing concentrating lens and supporting rail parts together.

9. A photovoltaic system, comprising:
a number of concentrating lenses, each having photovoltaic material;
a supporting rail; and
a clamping cover for securing each of the concentrating lenses to the supporting rail with, and for providing a busway for electrical wiring and interconnections associated with the photovoltaic material.

10. The system of claim 9 further comprising an optical coupling material in a cavity within each of the concentrating lenses.

11. The system of claim 10 wherein the optical coupling material is injected into a hole formed in a recess at an end of each concentrating lens, and the hole is blocked by the supporting rail when the corresponding concentrating lens is secured to the supporting rail.

12. The system of claim 9 wherein each of the concentrating lenses includes a hook-shaped end that is configured to interface with a complementary shape and geometry in the supporting rail, so that each concentrating lens can be temporarily secured to the supporting rail such that other concentrating lenses can be assembled adjacent to it, prior to installing the clamping cover.

13. The system of claim 9 wherein concentrating lens and supporting rail parts are fused together at one or more locations.

14. The system of claim 9 wherein each concentrating lens includes a filling hole for injecting optical coupling material, the hole being formed in a recess at an end of the concentrating lens, and connecting an exterior of the lens to a photovoltaic cavity in the lens that includes the photovoltaic material.

15. The system of claim 14 wherein a lower part of the filling hole is tapered to provide a seal when a tapered nozzle is inserted into the hole to fill the photovoltaic cavity with the optical coupling material.

16. The system of claim 15 wherein an upper part of the filling hole is wider than the tip of a tapered nozzle.

17. The system of claim 14 wherein each concentrating lens further includes a vent that allows for air to escape when the optically coupling material is injected into the photovoltaic cavity via the filling hole.

18. The system of claim 9 wherein one end of the clamping cover is configured to engage with a hook profile of at least one concentrating lens and an opposing end of the clamping cover is configured to be rotated into a locking interface formed between the clamping cover an the supporting rail.

19. A photovoltaic system, comprising:
a number of concentrating lenses, each having photovoltaic material and optical coupling material in a cavity within each concentrating lens;
a supporting rail; and
a clamping cover for securing each of the concentrating lenses to the supporting rail with, and for providing a busway for electrical wiring and interconnections associated with the photovoltaic material, wherein one end of the clamping cover is configured to engage with a hook profile of at least one concentrating lens and an opposing end of the clamping cover is configured to be rotated into a locking interface formed between the clamping cover an the supporting rail.

20. The system of claim 19 wherein each of the concentrating lenses includes a hook-shaped end that is configured to interface with a complementary shape and geometry in the supporting rail, so that each concentrating lens can be temporarily secured to the supporting rail such that other concentrating lenses can be assembled adjacent to it, prior to installing the clamping cover.
